(19) United States
(12) Patent Application Publication
(10) Pub. No.: US 2009/0061592 A1
(43) Pub. Date: Mar. 5, 2009

(54) SEMICONDUCTOR DEVICE AND MANUFACTURING METHOD THEREOF

(75) Inventors: Satoru ISOGAI, Tokyo (JP); Yasushi YAMAZAKI, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 12/196,589

(22) Filed: Aug. 22, 2008

(30) Foreign Application Priority Data
Aug. 30, 2007 (JP) 2007-223844

(51) Int. Cl. H01L 21/76

(52) U.S. Cl. 438/430; 257/E21.54

(57) ABSTRACT

A method of manufacturing the semiconductor device includes forming a first polysilicon film on an active region and an element isolation region made of a dielectric material provided in a semiconductor substrate; forming a hard mask on the first polysilicon film; etching the first polysilicon film, the semiconductor substrate in the active region and the dielectric material in the element isolation region by using the hard mask to form first and second gate trenches in the active region and the element isolation region, respectively; and filling the first and second gate trenches with a second polysilicon film before the hard mask is removed.

### BACKGROUND OF THE INVENTION

1. Field of the Invention

The present invention relates to a semiconductor device and a manufacturing method thereof, and, more particularly relates to a semiconductor device having a trench gate transistor, and a manufacturing method thereof.

2. Description of Related Art

In recent years, along the miniaturization of a DRAM (Dynamic Random Access Memory) cell, a gate length of a memory cell transistor has also become necessary to be shortened. However, when the gate length becomes shorter, a short-channel effect of the transistor becomes significant, and a sub-threshold current increases. When a substrate concentration is increased to restrict this current increase, a junction leakage increases. Therefore, aggravation of refresh characteristic of the DRAM becomes serious.

To avoid this problem, a trench gate transistor (also called a recess-channel transistor) having a gate electrode embedded into a trench formed in a silicon substrate is attracting attention (see Japanese Patent Application Laid-open Nos. 2005-322880 and 2007-134674). According to the trench gate transistor, an effective channel length (a gate length) can be physically sufficiently secured. A fine DRAM having a minimum process size equal to or shorter than 90 nm can be also realized.

A general manufacturing method of a trench gate transistor is explained below with reference to FIG. 16 to FIG. 26.

As shown in FIG. 16, a trench 201 is formed in a semiconductor substrate 200, and a thermal oxide film 202 is formed inside the trench 201 and on the front surface of the semiconductor substrate 200. Thereafter, the inside of the trench 201 is embedded with an element isolation insulating film (a silicon oxide film), thereby forming an element isolation region (for example, an STI region: element isolation region) 203. As a result, an active region isolated by the element isolation region 203 is formed.

Next, as shown in FIG. 17, a silicon nitride film is formed and then the silicon nitride film is patterned to form a hard mask 204 having an opening of a width “x” for a gate trench. Next, as shown in FIG. 18, gate trenches 205 are formed in the semiconductor substrate 200, and a gate trench 206 is formed in the element isolation region 203.

Next, as shown in FIG. 19, protection oxide films 207 each having a thickness of a few nm (about 5 to 10 nm) are formed by thermal oxidizing the inner surfaces of the gate trenches 205 formed in the semiconductor substrate 200. These protection oxide films 207 are formed to protect the semiconductor substrate 200 at the time of removing the silicon nitride film as the hard mask 204, using thermal phosphoric acid, in the subsequent process.

After removing the hard mask 204, as shown in FIG. 20, the protection oxide film 207 in the gate trench 205 and the thermal oxide film 202 on the surface of the semiconductor substrate 200 are removed by performing a wet etching using hydrofluoric acid.

As a result, the gate trenches 205 and 206 are completed. However, a width “y” of each gate trench 205 and a width “z” of the gate trench 206 become larger than the width “x” of the opening of the hard mask 204 shown in FIGS. 17 and 18. Reasons for this are explained below.

First, the increase in the width of the gate trench 205 is due to the formation of the protection oxide film 207 to protect the semiconductor substrate 200 at the time of removing the hard mask 204, in FIG. 19. That is, because the protection oxide film 207 is formed by thermal oxidization, the semiconductor substrate 200 is oxidized by a few nm. Therefore, when the protection oxide film 207 is removed by hydrofluoric acid, the width of the gate trench 205 becomes larger than the original width “x” by the oxidized few nm. As shown in FIG. 20, the width of the gate trench 205 becomes the width “y”.

The increase in the width of the gate trench 206 is due to the following. At the time of removing the protection oxide film 207 by the wet etching using hydrofluoric acid, the silicon oxide film forming the element isolation region 203 is exposed within the gate trench 206. Therefore, the element isolation region 203 is also etched. Particularly, because an over-etching is performed to completely remove the protection oxide film 207 from the inside of the gate trench 205, the width of the gate trench 206 tends to become large. As shown in FIG. 20, the width of the gate trench 206 becomes the width “z” much larger than the width “y” of the gate trench 205.

Therefore, as shown in FIG. 21, after the gate insulating film 208 is formed, a polysilicon film 209 is formed to be embedded into the gate trenches 205 and 206. Thereafter, as shown in FIG. 22, a resist mask 210 having a pattern of the width “x” as the design size is formed. When the polysilicon film 209 is patterned using this resist mask 210, a gate electrode 209g is not shaped to completely fill the gate trenches 205 and 206, as shown in FIG. 23. As a result, a gap is formed between the gate insulating film 208 on the inner surface of the gate trench 205 and the gate electrode 209g.

To avoid the state as shown in FIG. 23, when a patterning is performed using a resist mask 211 having a larger width than that of the resist mask 210, by considering the increased width of the gate trenches 205 and 206, as shown in FIG. 24, a gate electrode 212g is formed without a gap within the gate trenches 205 and 206, as shown in FIG. 25. However, in this case, a distance d, between the adjacent gate electrodes 212g becomes very small. Therefore, as shown in FIG. 26, a source/drain diffusion layer 213 is formed and thereafter when a contact plug 215 is formed to be connected to the source/drain diffusion layer 213, a space between the contact plug 215 and the gate electrode 212g becomes very small. That is, when the contact plug 215 is slightly deviated, the gate electrode 212g is short-circuited with the contact plug 215.

Further, because the width of the gate trench 206 in the element isolation region 203 (the width “z” in FIG. 20) is large, a distance d₂ between the gate electrode 212g formed in the gate trench 206 and the adjacent source/drain diffusion layer 213 becomes short. Consequently, parasitic capacitance becomes large.

As explained above, according to the above method, the widths “y” and z of the gate trenches 205 and 206 become larger than the width “x” as the design size. Further, to prevent a short-circuiting, a large margin needs to be taken between the gate electrodes 212g (between the gate trenches 205) and between the gate electrode 212g (the gate trench 206) and the source/drain diffusion layer 213. As a result, element miniaturization is difficult.

### SUMMARY

The present invention seeks to solve one or more of the above problems, or to improve upon those problems at least in part.

In one embodiment, there is provided a semiconductor device that includes an element isolation region provided in a semiconductor substrate; an active region isolated by the element isolation region in the semiconductor substrate; a first gate trench formed in the active region; a second gate trench formed in the element isolation region; and first and second gate electrodes parts of which respectively are embedded into the first and second gate trenches, wherein a width of the first gate trench is substantially equal to a width of the second gate trench.

In another embodiment, there is provided a manufacturing method of a semiconductor device that includes forming a first polysilicon film on an active region and an element isolation region made of a dielectric material provided in a semiconductor substrate; forming a hard mask on the first polysilicon film; etching the first polysilicon film, the semiconductor substrate in the active region and the dielectric material in the element isolation region by using the hard mask to form first and second gate trenches in the active region and the element isolation region, respectively; and filling the first and second gate trenches with a second polysilicon film before the hard mask is removed.

According to the present invention, the first polysilicon film is formed before forming a hard mask. Before removing the hard mask, the second polysilicon film becoming a gate electrode is embedded into the first and second gate trenches. Therefore, thereafter, in performing the wet etching by thermal phosphoric acid to remove the hard mask, the insides of the first and second gate trenches are protected by the second polysilicon film, and the semiconductor substrate and the element isolation region are protected by the first polysilicon film. Consequently, to protect the gate trench from the wet etching by the thermal phosphoric acid, a protection oxide film does not need to be formed separately. Further, because no protection oxide film is formed, the wet etching by hydrofluoric acid to remove the protection oxide film does not need to be performed. Accordingly, the increase in the widths of the first and second gate trenches can be prevented. As a result, the width of the first gate trench can be made substantially equal to the width of the second gate trench.

Because the increase in the widths of the first and second gate trenches can be prevented, an unnecessary margin does not need to be taken in the interval between the adjacent gate trenches (gate electrodes). Therefore, the elements can be miniaturized.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic top plan view for explaining a configuration of a semiconductor device according to an embodiment of the present invention;

FIG. 2 is a cross section of one process (formation of an element isolation region 103) of a manufacturing method of a semiconductor device according to a preferred embodiment of the present invention;

FIG. 3 is a cross section of one process (removal of a thermal oxide film 102) of the manufacturing method of the semiconductor device according to the preferred embodiment of the present invention;

FIG. 4 is a cross section of one process (formation of a thermal oxide film 10) of the manufacturing method of the semiconductor device according to the preferred embodiment of the present invention;

FIG. 5 is a cross section of one process (formation of a first polysilicon film 104) of the manufacturing method of the semiconductor device according to the preferred embodiment of the present invention;

FIG. 6 is a cross section of one process (formation of a silicon nitride film 105) of the manufacturing method of the semiconductor device according to the preferred embodiment of the present invention;

FIG. 7 is a cross section of one process (formation of a hard mask 105h) of the manufacturing method of the semiconductor device according to the preferred embodiment of the present invention;

FIG. 8 is a cross section of one process (formation of gate trenches 106 and 107) of the manufacturing method of the semiconductor device according to the preferred embodiment of the present invention;

FIG. 9 is a cross section of one process (formation of a thermal oxide film 108) of the manufacturing method of the semiconductor device according to the preferred embodiment of the present invention;

FIG. 10 is a cross section of one process (formation of a second polysilicon film 109) of the manufacturing method of the semiconductor device according to the preferred embodiment of the present invention;

FIG. 11 is a cross section of one process (etching back of the second polysilicon film 109) of the manufacturing method of the semiconductor device according to the preferred embodiment of the present invention;

FIG. 12 is a cross section of one process (removal of the hard mask 105h) of the manufacturing method of the semiconductor device according to the preferred embodiment of the present invention;

FIG. 13 is a cross section of one process (formation of a resist mask 110) of the manufacturing method of the semiconductor device according to the preferred embodiment of the present invention;

FIG. 14 is a cross section of one process (formation of gate electrodes 109g) of the manufacturing method of the semiconductor device according to the preferred embodiment of the present invention;

FIG. 15 is a cross section of one process (formation of source/drain diffusion layers 111 to formation of capacitors 115) of the manufacturing method of the semiconductor device according to the preferred embodiment of the present invention;

FIG. 16 is a cross section of one process (formation of an element isolation region 103) of a manufacturing method of a semiconductor device according to a related art;

FIG. 17 is a cross section of one process (formation of a hard mask 204) of the manufacturing method of the semiconductor device according to the related art;

FIG. 18 is across section of one process (formation of gate trenches 205 and 206) of the manufacturing method of the semiconductor device according to the related art;

FIG. 19 is a cross section of one process (formation of protection oxide films 207) of the manufacturing method of the semiconductor device according to the related art;

FIG. 20 is a cross section of one process (removal of the protection oxide films 207) of the manufacturing method of the semiconductor device according to the related art;

FIG. 21 is a cross section of one process (formation of a gate insulating film 208 and a polysilicon film 209) of the manufacturing method of the semiconductor device according to the related art;

FIG. 22 is a cross section of one process (formation of a resist mask 210) of the manufacturing method of the semiconductor device according to the related art;

FIG. 23 is a cross section of one process (formation of gate electrodes 209g) of the manufacturing method of the semiconductor device according to the related art;

FIG. 24 is a cross section of one process (formation of a resist mask 211) of the manufacturing method of the semiconductor device according to the related art;

FIG. 25 is a cross section of one process (formation of a gate electrodes 212g) of the manufacturing method of the semiconductor device according to the related art; and

FIG. 26 is a cross section of one process (formation of a contact plug 215) of the manufacturing method of the semiconductor device according to the related art.

### DETAILED DESCRIPTION OF THE EMBODIMENTS

Preferred embodiments of the present invention will be explained below in detail with reference to the accompanying drawings.

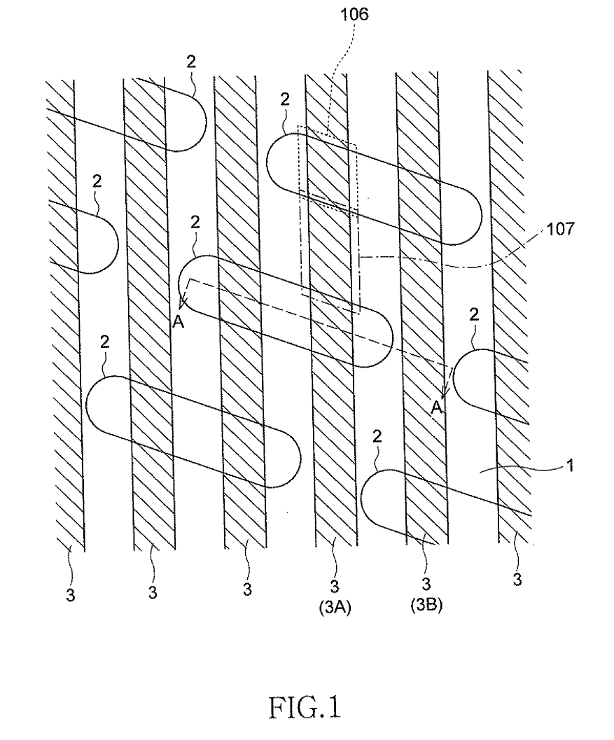

FIG. 1 is a schematic top plan view for explaining a configuration of a semiconductor device according to an embodiment of the present invention.

As shown FIG. 1, the semiconductor device according to the embodiment includes an element isolation region 1, and plural active regions 2 isolated and surrounded by the element isolation region 1. Plural gate trenches (gate electrodes) 3 are laid out in parallel so that two gate trenches are included in each active region 2. Each of the gate trenches (gate electrodes) 3 is formed to go over the plural active regions 2.

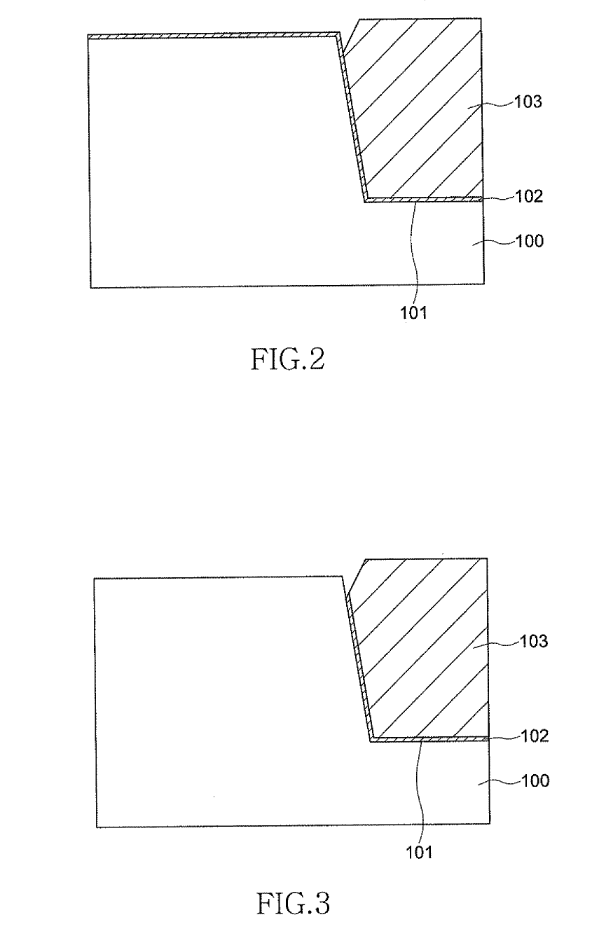

FIG. 2 to FIG. 15 are process diagrams schematically showing a manufacturing process of the semiconductor device having a trench gate transistor according to the embodiment. FIG. 2 to FIG. 15 are cross-sectional views taken along a line A-A in FIG. 1.

As shown in FIG. 2, a trench 101 is formed on a semiconductor substrate 100, and a thermal oxide film 102 is formed on the inside of the trench 101 and on the surface of the semiconductor substrate 100. Thereafter, the inside of the trench 101 is embedded with an element isolation insulating film (a silicon oxide film), thereby forming an element isolation region (for example, an STI region) 103. As a result, as shown in FIG. 1, the active regions 2 isolated by the element isolation region 1 (103) are formed.

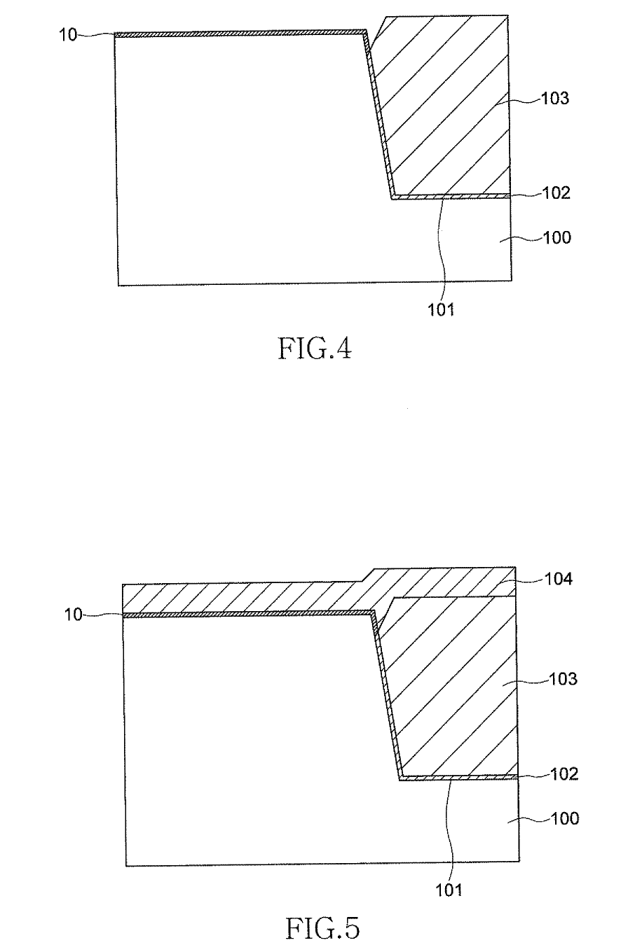

Next, as shown in FIG. 3, the thermal oxide film 102 on the surface of the semiconductor substrate 100 is removed. The thermal oxide film 102 plays a role of a protection film to remove a silicon-nitride film (not shown) used as a hard mask at the time of forming the trench 101, by thermal phosphoric acid. When the thermal oxide film 102 is used as it is as a gate insulating film, reliability decreases, and this becomes a cause of a gate leakage and a withstand-pressure failure. Therefore, after the thermal oxide film 102 on the surface of the semiconductor substrate 100 is removed, a new thermal oxide film 10 becoming a part of the gate insulating film is formed on the surface of the semiconductor substrate 100 as shown in FIG. 4.

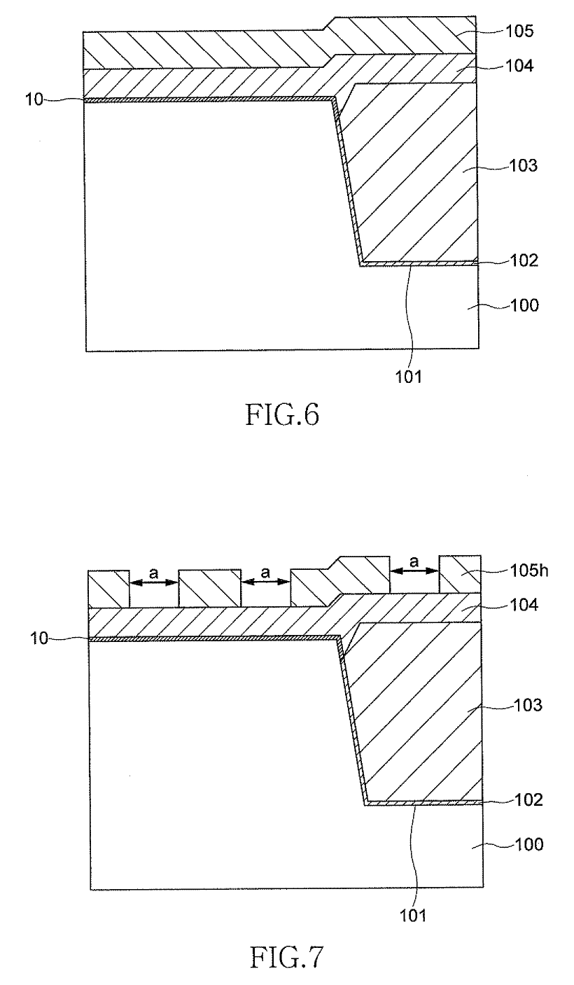

Next, as shown in FIG. 5, a first polysilicon film 104 is formed on the whole surface. As shown in FIG. 6, a silicon nitride film 105 is formed on the first polysilicon film 104.

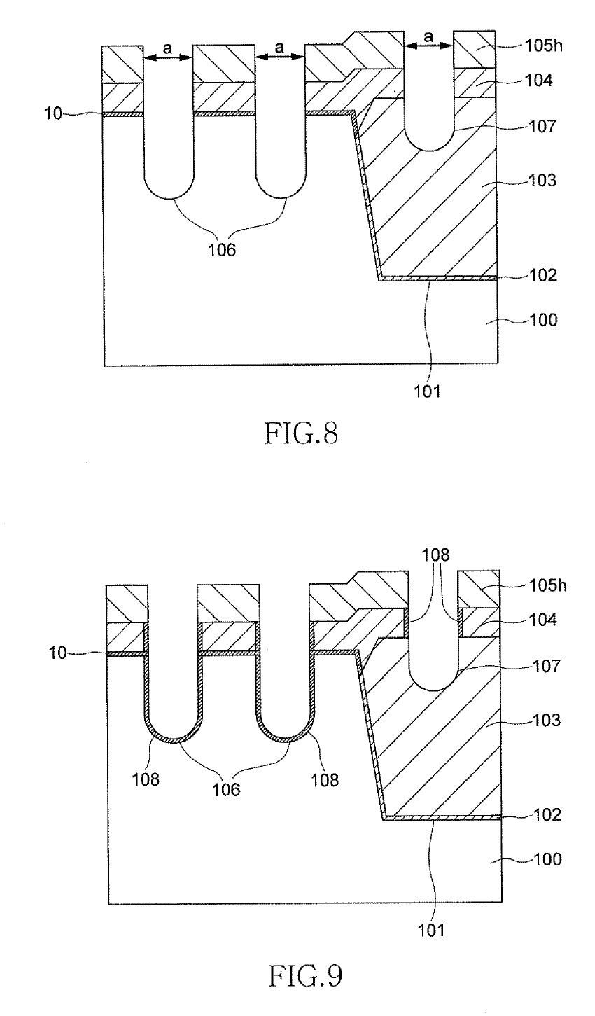

Next, as shown in FIG. 7, the silicon nitride film 105 is patterned to form a hard mask 105h having an opening of a width “a” for a gate trench. Thereafter, as shown in FIG. 8, the first polysilicon film 104 is etched using the hard mask 105h as a mask, and further, the semiconductor substrate 100 and the element isolation region 103 are etched, thereby forming gate trenches 106 in the semiconductor substrate 100 of the active region and forming gate trenches 107 in the element isolation region 103.

Next, as shown in FIG. 9, a thermal oxidization is performed without removing the hard mask 105h, thereby forming a thermal oxide film 108 becoming a gate insulating film on the inner surface of each gate trench 106. In this case, the thermal oxide film 108 is also formed on the side surface of the first polysilicon film 104.

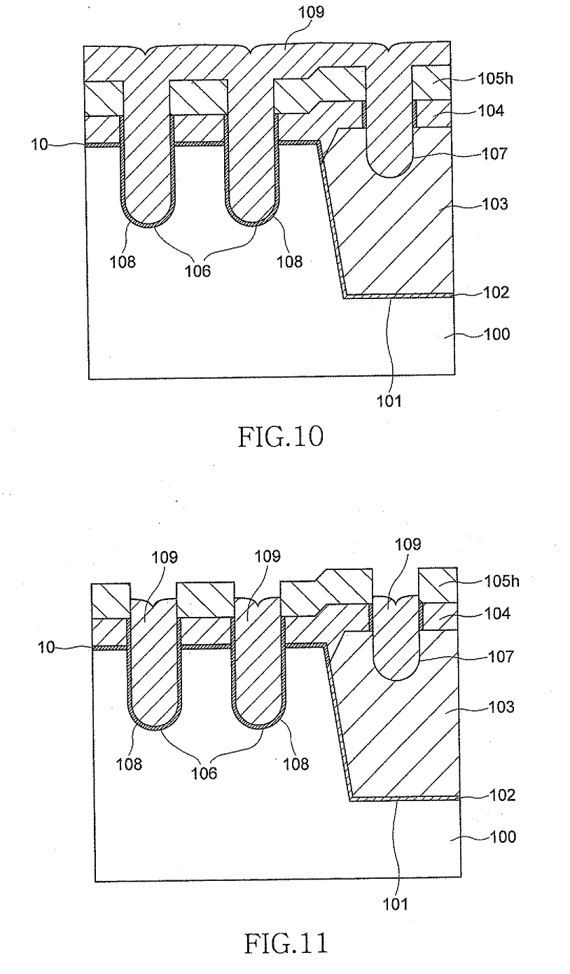

Next, as shown in FIG. 10, a second polysilicon film 109 is formed on the whole surface to be embedded in each gate trench 106 and gate trench 107, in a state that the hard mask 105h is kept formed. Next, as shown in FIG. 11, the whole surface is dry-etched, and the second polysilicon film 109 is etched back to near the height of the first polysilicon film 104.

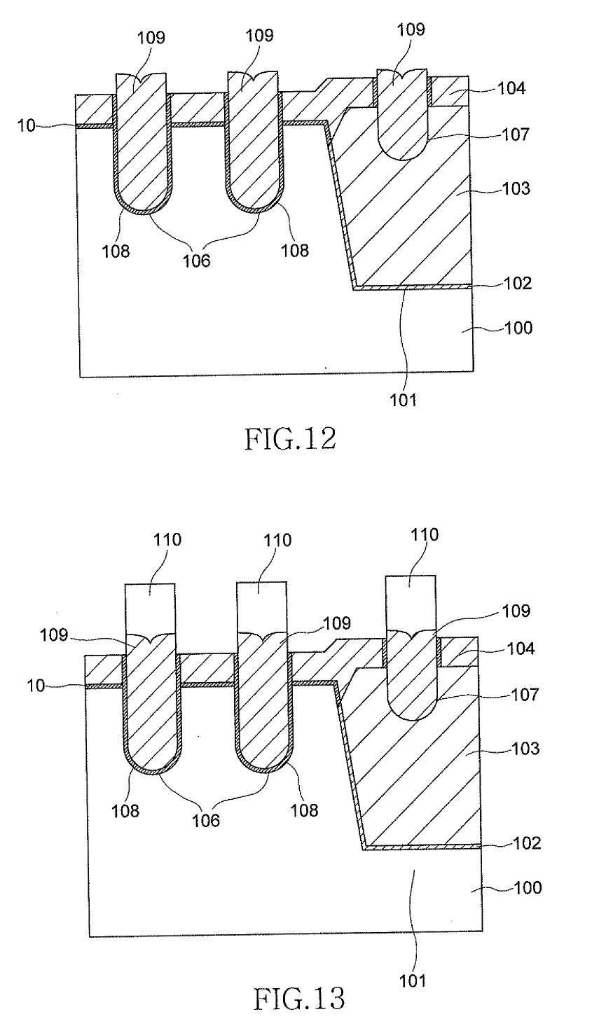

Thereafter, a wet etching is performed using thermal phosphoric acid, and the hard mask (the silicon nitride film) 105h is removed, thereby obtaining a state shown in FIG. 12. In this case, the thermal oxide film 108 and the second polysilicon film 109 are kept formed within each gate trench 106 formed in the active region of the semiconductor substrate 100. Accordingly, the inner surface of each gate trench 106 is protected, and the surface of the semiconductor substrate 101 is protected by the first polysilicon film 104. Consequently, a protection oxide film does not need to be separately formed to protect the gate trenches 106 and the semiconductor substrate 100 from the wet etching by thermal phosphoric acid. Because no protection oxide film is formed, a wet etching using hydrofluoric acid does not need to be performed to remove this protection oxide film. As a result, the increase in the width of the gate trenches 106 and 107 can be prevented.

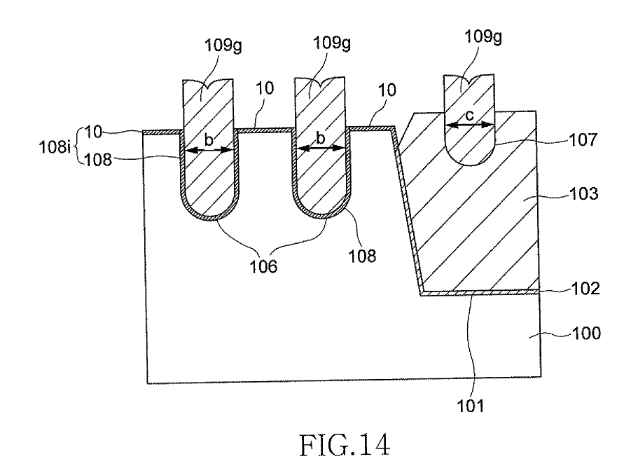

As shown in FIG. 13, a resist mask 110 having a gate-electrode-shape pattern is formed on the second polysilicon film 109. Next, the first polysilicon film 104 is removed by etching, using the resist mask 110. Simultaneously, parts of the silicon oxide film 108 on side surfaces of the first polysilicon film 104 are also removed. As a result, gate electrodes 109g are completed, as shown in FIG. 14. The thermal oxide film 108 remaining within the gate trench 106 and the thermal oxide film 10 on the surface of the semiconductor substrate 100 become gate insulating films 108i.

When each gate electrode 109g is completed, the gate trench 106 has a width “b” and the gate trench 107 has a width “c”, which are substantially equal widths, as shown in FIG. 14. These widths are also substantially equal to the width “a” of the opening of the hard mask 105h shown in FIG. 7.

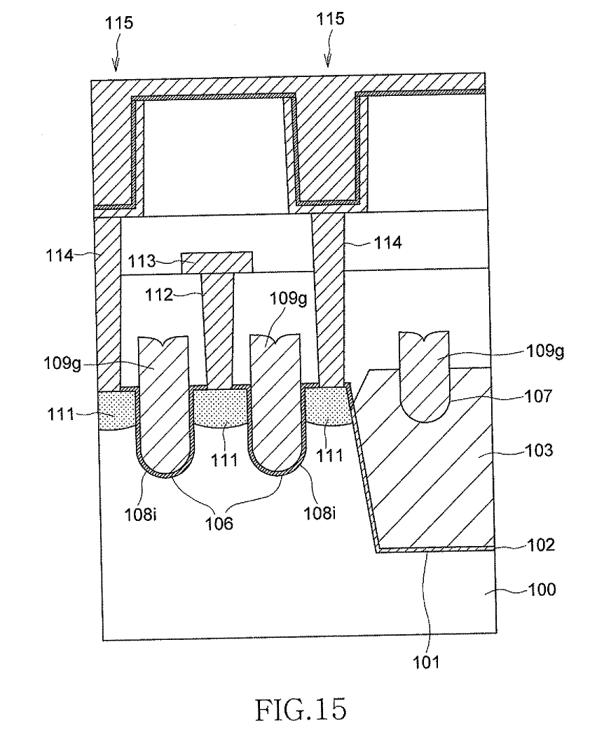

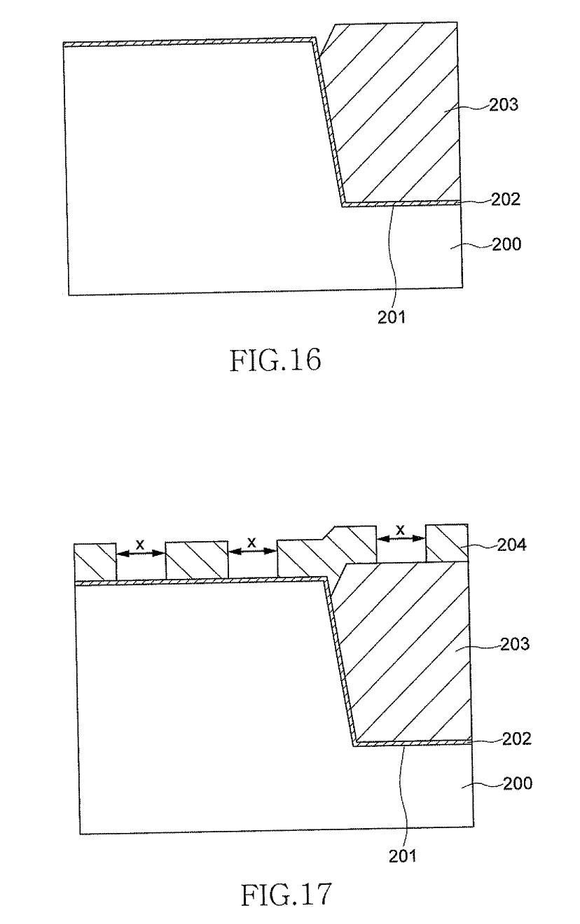

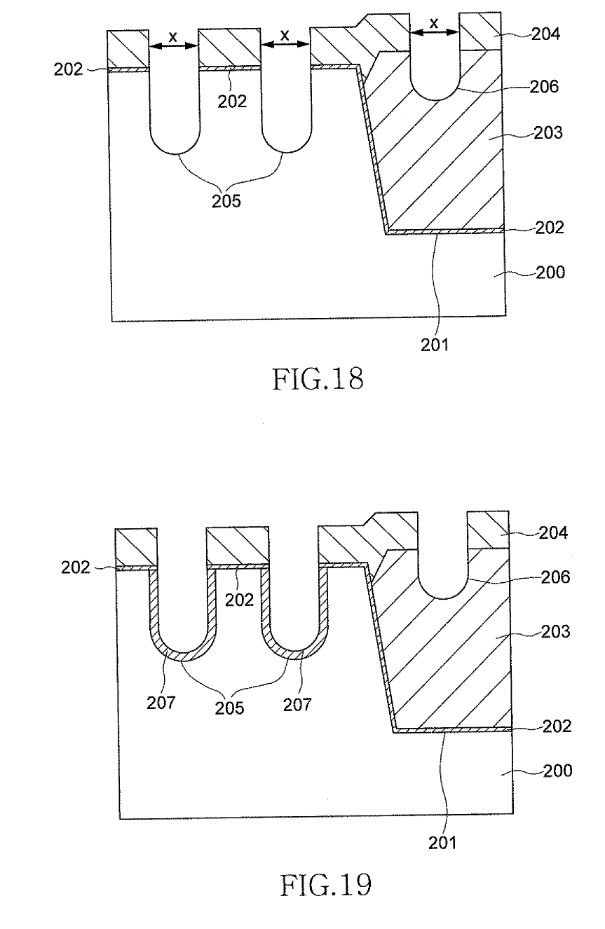

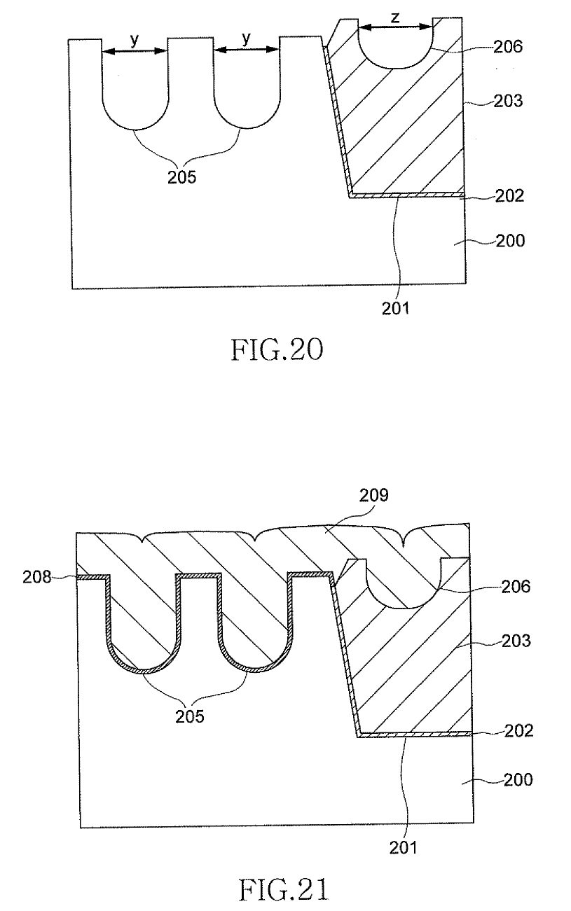

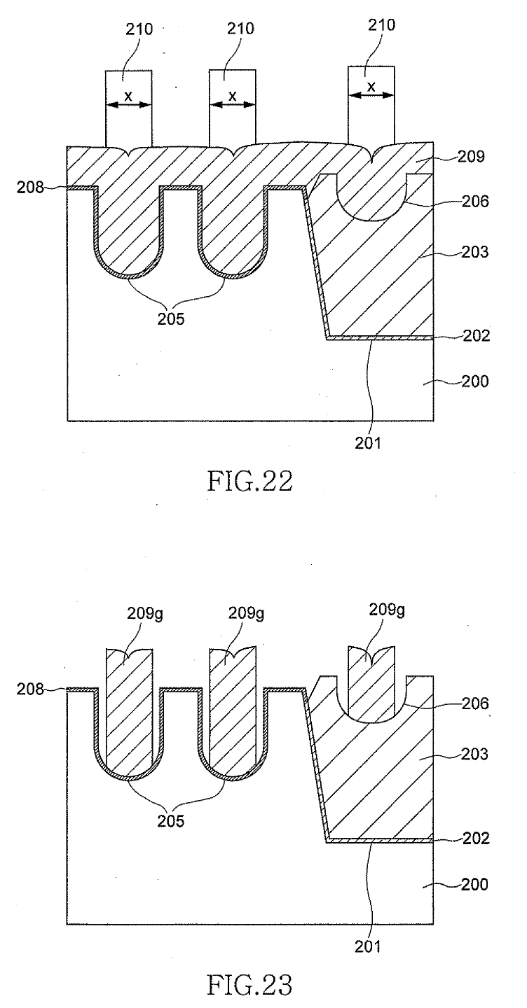

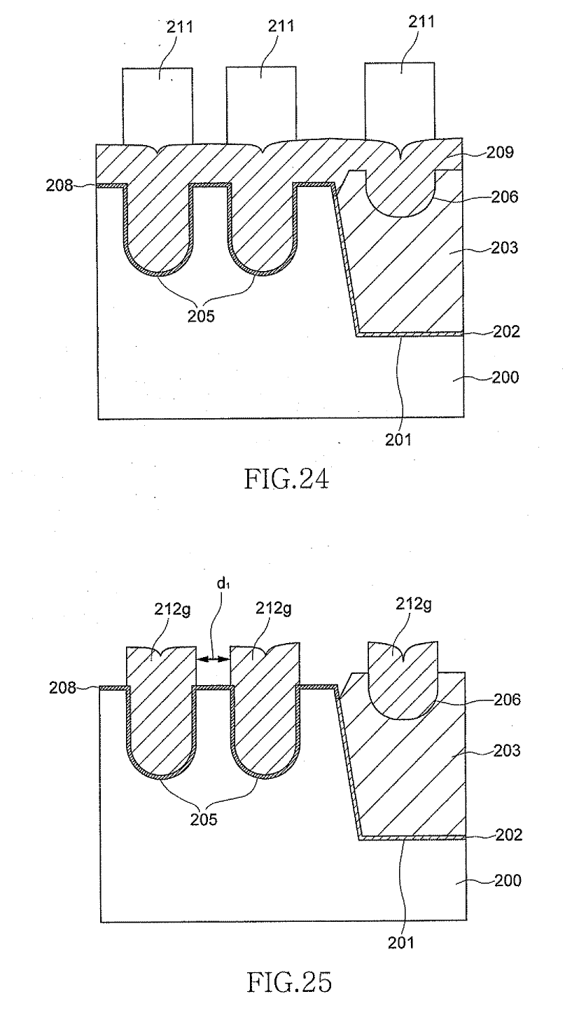

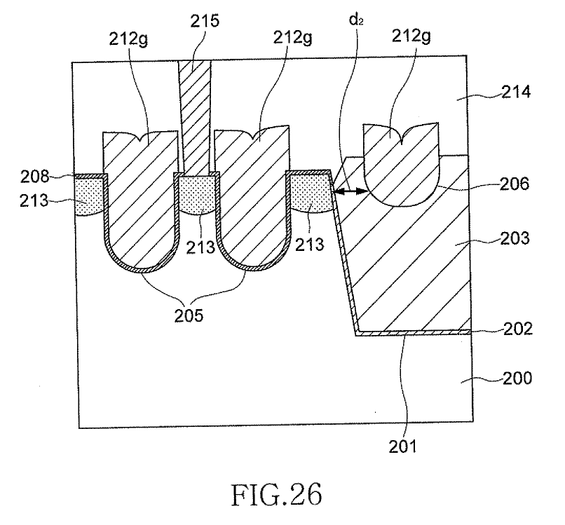

Thereafter, various wirings are laminated using a general method. As shown in FIG. 15, source/drain diffusion layers 111 are formed in the semiconductor substrate 100. Further, a contact plug 112, a wiring 113, contact plugs 114, and capacitors 115 are formed, thereby completing a semiconductor device (DRAM) having a trench gate transistor. Because each gate trench 106 (the gate electrode 109g) has a width substantially equal to a design size (that is, “a” is substantially equal to “b”), a distance between the adjacent gate electrodes 109g is sufficiently secured. Therefore, a margin between the contact plug 112 and the gate electrode 109g can be secured, thereby restricting a short-circuiting between the contact plug 112 and the gate electrode 109g. Because there is a sufficiently large distance between the gate electrode 109g formed within the gate trench 107 and the adjacent source/drain diffusion layer 111, parasitic capacitance can be restricted.

In the present embodiment, as shown in FIG. 15, a part of the gate electrode 109g is embedded into the gate trench 107, in the element isolation region 103. That is, as shown in FIG. 1, the gate electrodes 3 (109g) going over the plural active regions 2 are embedded into the gate trenches 106 in the active regions 2 (the semiconductor substrate 100), and are embedded into the gate trenches 107 in the element isolation region 1 (103). According to this configuration, the gate electrodes 109g can secure large cross-sectional areas at respective positions in their extending directions. Therefore, their resistance values can be made sufficiently small at any positions of the gate electrodes 3 (109g). As a result, the transistor can operate at a high speed.

FIG. 2 to FIG. 15 explain the manufacturing process according to the present embodiment, and these drawings are cross-sectional views taken along the line A-A in FIG. 1. Therefore, the gate trench 106 at the right side within the active region shows a part of a gate electrode 3A in FIG. 1, and the gate trench 107 within the element isolation region shows a part of a gate electrode 38 adjacent to the gate electrode 3A. However, when one gate electrode is looked at, the gate trench 106 and the gate trench 107 can be understood as constituent parts of this gate electrode. That is, as shown by a dotted line and a dashed line in FIG. 1, in one gate electrode 3A (109g), a part which is present in the active region 2 and encircled by the dotted line constitutes the gate trench 106, and a part which is present in the element isolation region I and encircled by the dashed line constitutes the gate trench 107. That is, the gate trench 106 and the gate trench 107 are connected to each other. Further, the gate trench 106 and the gate trench 107 have substantially equal widths.

As explained above, according to the present embodiment, the widths of the gate trenches 106 and 107 can be formed in substantially the design size. Therefore, an unnecessary margin does not need to be taken, elements can be miniaturized. A reticle (a mask) for forming the gate trenches 106 and 107 and a reticle (a mask) for forming the gate electrode 109g can be shared.

It is apparent that the present invention is not limited to the above embodiments, but may be modified and changed without departing from the scope and spirit of the invention.

For example, in the above embodiment, while the gate electrode 109g is formed using only a polysilicon film, a metal silicide film and a metal film can be laminated on the polysilicon film, and these can be patterned to form a gate electrode.

What is claimed is:

1. A semiconductor device comprising:
an element isolation region provided in a semiconductor substrate;
an active region isolated by the element isolation region in the semiconductor substrate;
a first gate trench formed in the active region;
a second gate trench formed in the element isolation region; and
first and second gate electrodes of which respectively are embedded into the first and second gate trenches, wherein
the first and second gate trenches have substantially a same width as each other.

2. A method of manufacturing a semiconductor device, comprising:
forming an element isolation region made of a first insulation film in a semiconductor substrate, and an active region isolated by the element isolation region;
forming a first polysilicon film on the active region and the element isolation region;
forming a hard mask made of a second insulation film on the first polysilicon film;
etching the first polysilicon film and the semiconductor substrate in the active region, and etching the first polysilicon film and the first insulation film in the element isolation region, using the hard mask, thereby forming a first gate trench in the active region in the semiconductor substrate, and forming a second gate trench in the first insulation film in the element isolation region;
forming a gate insulating film on an inner surface of the first gate trench, while leaving the hard mask;
forming a second polysilicon film becoming a gate electrode, so as to be embedded in the first and second gate trenches, while leaving the hard mask;
removing the hard mask in a state that the second polysilicon film is embedded in the first and second gate trenches; and
removing the first polysilicon film.

3. The method of manufacturing the semiconductor device as claimed in claim 2, wherein the first and second gate trenches have substantially a same width as each other.

4. The method of manufacturing the semiconductor device as claimed in claim 2, wherein the first insulation film is made of a silicon oxide.

5. The method of manufacturing the semiconductor device as claimed in claim 2, wherein the second insulation film is made of a silicon nitride.

6. The method of manufacturing the semiconductor device as claimed in claim 5, wherein the hard mask is removed by wet etching using thermal phosphoric acid.

7. A method of manufacturing the semiconductor device comprising:
forming a first polysilicon film on an active region and an element isolation region made of a dielectric material provided in a semiconductor substrate;
forming a hard mask on the first polysilicon film;
etching the first polysilicon film, the semiconductor substrate in the active region and the dielectric material in the element isolation region by using the hard mask to form first and second gate trenches in the active region and the element isolation region, respectively; and
filling the first and second gate trenches with a second polysilicon film before the hard mask is removed.

8. The method of manufacturing the semiconductor device as claimed in claim 7, wherein the first and second gate trenches have substantially a same width as each other.

9. The method of manufacturing the semiconductor device as claimed in claim 7, wherein the dielectric material is a silicon oxide.

10. The method of manufacturing the semiconductor device as claimed in claim 7, wherein the hard mask is made of a silicon nitride.

11. The method of manufacturing the semiconductor device as claimed in claim 10, wherein the hard mask is removed by wet etching using thermal phosphoric acid.
